(19) United States
(12) Patent Application Publication
(10) Pub. No.: US 2026/0146139 A1
(43) Pub. Date: May 28, 2026

(54) BIO-BASED EPOXY MOLD COMPOUND FOR ELECTRONIC DEVICES

(71) Applicant: Sandisk Technologies, Inc., Milpitas, CA (US)

(72) Inventors: VIGNESHWARRAM KUMARESAN, BATU KAWAN (MY); VISHNU CHANDAR JANAKIRAMAN, BATU KAWAN (MY); MUTHARASU DEVARAJAN, Fremont, CA (US)

(21) Appl. No.: 18/956,989

(22) Filed: Nov. 22, 2024

(51) Int. Cl. C08K 3/08; C08K 3/016; H01L 23/29

(52) U.S. Cl. CPC C08K 3/08; C08K 3/016; H10W 74/473; C08K 2003/0818; C08K 2003/0856; C08K 2201/018

(57) ABSTRACT

A bio-based epoxy molding compound (EMC) is comprised of over ninety percent bio-based and/or biodegradable materials such as, basalt fillers, bio-based epoxy resins, bio-based releasing agents and bio-based stress modifiers. The bio-based EMC is a sustainable alternative to conventional EMCs and provides enhanced mechanical strength, enhanced thermal stability and performance, and enhanced chemical resistance when compared with conventional EMCs.

### BACKGROUND

Epoxy molding compounds (EMCs) are a critical part of most semiconductor packages. An EMC is typically used to encapsulate and protect the various electronic components of the semiconductor package such as integrated circuits, transistors, and diodes. For example, the EMC provides a protective layer that shields these electronic components from environmental factors like moisture, dust, and chemicals, which helps prevent corrosion and damage. The EMCs also provide mechanical support and stability for the various electronic components as well as electrical isolation and thermal conductivity.

However, conventional EMCs have a significant environmental impact due, in part, to the manufacturing processes and the materials that are used for production. For example, conventional EMCs are manufactured using non-renewable resources such as petroleum-based resins and silica fillers. Extracting and processing silica is energy-intensive, which can lead to significant carbon emissions.

Accordingly, it would be beneficial to reduce the environmental impacts of EMC production and disposal by replacing conventional EMCs with environmentally friendly materials while maintaining or improving the thermal and mechanical properties of the EMC.

### SUMMARY

The present application describes a bio-based epoxy molding compound (EMC) for an electronic device such as, for example, a semiconductor package. Although a semiconductor package is specifically mentioned, the bio-based EMC can be used across a number of different industries and in a number of different applications.

Unlike conventional EMCs, that are mostly comprised of non-renewable and non-naturally occurring materials such as petroleum-based resins and silica fillers, the bio-based EMC of the present disclosure is primarily made from naturally occurring materials. Indeed, in some implementations, the bio-based EMC described herein is comprised of over ninety percent (90%) bio-based and/or biodegradable materials.

For example, instead of using silica fillers like conventional EMCs, the bio-based EMC of the present disclosure uses natural fillers made from naturally occurring materials. In one example, the natural filler is basalt powder. In other examples, instead of using non-biobased epoxy resins, such as Bisphenol A (which is used in conventional EMCs), the bio-based EMC of the present disclosure uses bio-based epoxy resins (e.g., epoxy resins that have twenty-eight (28%) of carbon derived from plants). Additionally, and unlike conventional EMCs that use silicon-based compounds and synthetic waxes for releasing agents, the bio-based EMC of the present disclosure uses biodegradable wax and other biodegradable materials.

These bio-based materials not only offer a sustainable alternative to conventional EMCs, but do not compromise the mechanical strength and thermal stability of the bio-based EMC which is typically required for high-performance applications.

Accordingly, examples of the present disclosure describe an epoxy molding compound (EMC) for an electronic device. In an example, the EMC is comprised of a bio-based filler material having a first weight percentage in a range of sixty weight percentage and ninety weight percentage of a total material composition of the EMC. The EMC also includes a bio-based epoxy resin having a second weight percentage in a range of one weight percentage and a thirty weight percentage of the total material composition of the EMC.

The present disclosure also describes an EMC for an electronic device. In this example, the EMC includes a bio-based filling means having a first weight percentage in a range of sixty weight percentage and ninety weight percentage of a total material composition of the EMC. The EMC also includes an epoxy resin means having a second weight percentage in range of one weight percentage and thirty weight percentage of the total material composition of the EMC.

Still other examples describe an electronic device having a substrate and a semiconductor die communicatively coupled to the substrate. A bio-based EMC encapsulates the semiconductor die. In an example, the bio-based EMC is comprised of at least ninety percent by weight of bio-based materials.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a semiconductor package having a bio-based epoxy molding compound (EMC) according to an example.

FIG. 2 is a table that includes four example compositions for a bio-based EMC according to an example.

FIG. 3 is a table that includes properties for four example compositions of a bio-based EMC according to an example.

FIG. 4 illustrates a method for creating a bio-based EMC powder that may be used to create a bio-based EMC according to an example.

FIG. 5 illustrates a method for creating a bio-based EMC according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Epoxy molding compounds (EMCs) are included in most, if not all, semiconductor packages and/or electronic devices. Typically, the EMC encapsulates and protects the various electronic components of the semiconductor package. For example, the EMC encapsulates integrated circuits, transistors, diodes and other electronic components of the semiconductor package to provide protection from environmental factors. The EMC also provides mechanical support, electrical isolation and thermal conductivity.

However, conventional EMCs have a significant and negative impact on the environment. For example, conventional EMCs are manufactured using non-renewable resources such as petroleum-based resins and silica fillers. Extracting and processing silica is energy-intensive, which can lead to significant carbon emissions.

To address the above, the present application describes an EMC for an electronic device, such as, for example, a semiconductor package. The EMC described herein is primarily made from naturally occurring and/or bio-based materials. Indeed, and as will be explained in greater detail below, the EMC of the present disclosure is comprised of at least ninety percent (90%) bio-based and/or biodegradable materials.

For example, the EMC of the present disclosure uses renewable and/or bio-based materials, such as bio-based epoxy resins, basalt powder, and eco-friendly additives. These bio-based materials offer a sustainable alternative to traditional petroleum-based components that are used in conventional EMCs and do not compromise the mechanical strength and/or thermal stability required for high-performance applications.

The EMC described herein has many environmental benefits. For example, the inclusion of basalt powder as a filler instead of silica powder reduces CO₂ emissions. Additionally, by using bio-based materials, such as plant-derived epoxy resins and biodegradable additives, the environmental footprint of the EMC is significantly reduced when compared with conventional EMCs. Additionally, the use of renewable resources helps lower greenhouse gas emissions and supports sustainable manufacturing practices.

In addition to the environmental impacts, the EMC described herein has other technical advantages including, but not limited to, enhanced mechanical strength, enhanced thermal stability and performance when compared with conventional EMCs. For example, the combination of bio-based epoxy resin and basalt powder significantly enhances the mechanical strength of the EMC when compared with conventional EMCs as basalt powder contributes to high tensile and compressive strength.

Additionally, the EMC described herein exhibits excellent thermal stability which enables the EMC to perform well in high-temperature environments. For example, basalt powder enhances heat resistance, while the bio-based resins provide consistent thermal behavior. The EMC described herein also has better thermal conductivity and a better coefficient of thermal expansion (CTE) when compared to conventional EMCs.

Additionally, and although the examples described herein are directed to EMCs for semiconductor packages, the bio-based EMC described herein is suitable for other implementations including, but not limited to, the encapsulation of electronic components, use in the auto industry, and use in the renewable energy sector to name a few. For example, the EMC described herein may be used in the auto industry for manufacturing or producing lightweight composite panels, which reduces vehicle weight and improves fuel efficiency. In other examples, the bio-based EMC can be used in the renewable energy sector. For example, the EMC can be used for solar panel encapsulation to shield or protect solar panels from environmental damage, which will improve the efficiency and lifespan of the panels.

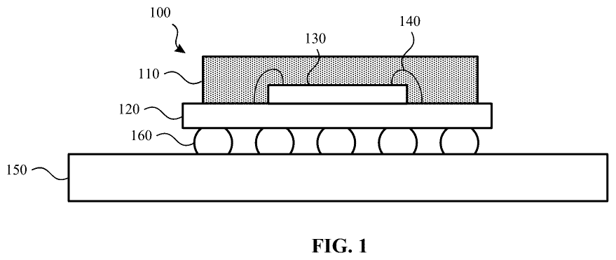

These and other examples will be shown and described in greater detail with respect to FIG. 1-FIG. 5.

FIG. 1 illustrates a semiconductor package 100 having a bio-based EMC 110 according to an example. Although the bio-based EMC 110 is shown as being part of the semiconductor package 100, the bio-based EMC 110 (also referred to as an EMC 110) can be used in other industries and/or applications.

In this example, the semiconductor package 100 includes a substrate 120. An integrated circuit, or a semiconductor die 130, is electrically coupled to the substrate 120 using, for example, one or more bond wires 140. In an example, the semiconductor die 130 is a NAND memory die, although this is not required.

The EMC 110 encapsulates the semiconductor die 130, the bond wires 140 and other electronic components (not shown) of the semiconductor package 100. In this example, the semiconductor package 100 is electrically coupled to a printed circuit board (PCB) 150 using one or more connection mechanisms 160 (e.g., solder balls). Although solder balls are shown and described, the semiconductor package 100 may be electrically and/or communicatively coupled to the PCB 150 using other connection mechanisms 160.

In an example, the EMC 110 is primarily comprised of a natural filler, such as, for example, a basalt powder filler. Although basalt powder is specifically mentioned, other natural fillers can be used.

Basalt is derived from volcanic rock which is a natural and an abundant resource. Additionally, the production of basalt powder and requires less energy and produces fewer CO₂ emissions when compared to the production of silica powder. As a result, manufacturing EMCs with basalt powder has a lower environmental impact.

Basalt powder is also more eco-friendly when compared with silica powder in terms of waste generation. Basalt powder is also naturally resistant to moisture and degradation which leads to longer product lifecycles. Additionally, basalt powder-based EMCs can be recycled more easily than EMCs that use conventional materials.

In an example, the basalt powder as a filler constitutes between approximately sixty (60) weight percentage (wt. %) and approximately ninety (90) wt. % of the total weight of the composition of the EMC 110. Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/−10% of the stated value(s).

In another example, basalt powder as a filler constitutes between approximately seventy (70) weight percentage (wt. %) and approximately eighty-five (85) wt. % of the total weight of the composition of the EMC 110. Although specific ranges are given, the basalt powder filler can be less than sixty (60) weight percentage (wt. %) or greater than ninety (90) wt. %.

As previously discussed, basalt powder as a filler offers various advantages when used in composite materials when compared with conventional fillers, such as silica. For example, basalt powder provides enhanced mechanical strength, excellent thermal stability, and improved thermal conductivity when compared to silica. Basalt powder also provides good chemical resistance, is environmentally friendly, and contributes to dimensional stability under temperature fluctuations. The basalt power is also fire resistant, corrosion resistant and is relatively lightweight.

The EMC 110 is also comprised of a bio-based epoxy resin. In an example, the amount of the bio-based epoxy resin in the EMC 110 is in a range of approximately one (1) wt. % and approximately thirty (30) wt. % based on the total weight of the composition that comprises the EMC 110. In another example, the amount of the bio-based epoxy resin in the EMC 110 is in a range of approximately five (5) wt. % and approximately twenty-five (25) wt. % based on the total weight of the composition that comprises the EMC 110.

In an example, the bio-based may be any bio-based resin. For example, the EMC 110 includes an epoxy resin having approximately twenty-eight percent (28%) of carbon originating from plants. Although a specific percentage is given, the percentage of carbon originating from plants may be higher than twenty-eight percent or lower than twenty-eight percent. In an example, the bio-based epoxy resin used in the EMC 110 is bisphenol A diglycidyl ether (2,2′-[(1-METHYLETHYLIDENE)BIS(4,1-PHENYLENEOXYMETHYLENE)]BISOXIRANE). Although bisphenol A diglycidyl ether is specifically mentioned, other bio-based epoxy resins may be used. In an example, bisphenol A diglycidyl ether is used in the EMC 110 because this particular bio-based epoxy has lower environmental impact than standard bisphenol-A epoxy, which is used in conventional EMCs.

The EMC 110 also includes a hardener or curing agent. In an example, the hardener or curing agent used in the EMC 110 is isophorone diamine. Although isophorone diamine is specifically mentioned, other curing agents may be used. In an example, the amount of curing agent in the composition that comprises the EMC 110 is in a range of approximately one (1) wt. % and approximately ten (10) wt. %. In another example, the amount of hardener in the composition is in a range of approximately one (1) wt. % and approximately six (6) wt. %.

In an example, the EMC 110 is also comprised of a flame retardant. While any suitable flame retardant can be used for the EMC 110, an eco-friendly flame retardant such as, for example, a non-halogen flame retardant with low toxicity and low smoke characteristics, may be selected and used to further reduce the environmental impact of the EMC 110. In an example, the amount of flame retardant in the composition is in a range of approximately zero (0) wt. % and approximately five (five) wt. %. In another example, the amount of flame retardant in the composition is in a range of approximately zero (0) wt. % and approximately three (3) wt. %. Although specific ranges are given, other ranges may be used.

In an example, wax is used as a releasing agent in the composition that comprises the EMC 110. Although any type of wax/releasing agent may be used, an eco-friendly or a biodegradable wax may be used to further reduce the environmental impact of the EMC 110. In an example, biodegradable waxes do not have microplastics like conventional waxes (e.g., polyethylene waxes, polypropylene waxes, silica-coated waxes).

In an example, the amount of wax/releasing agent in the composition that comprises the EMC 110 is in a range of approximately zero (0) wt. % and approximately five (5) wt. %. In another example, the amount of wax/releasing agent in the composition is in a range of approximately zero point one (0.1) wt. % and approximately two (2) wt. %. Although specific ranges are given, other ranges may be used.

The composition that makes up the EMC 110 may also include ion trapping agents. In an example, ion trapping agents are used in the EMC 110 to help ensure better electrical insulation, prevent ionic migration, enhance moisture resistance, and improve the chemical stability of the encapsulated electronic components. All of these factors significantly increases the reliability and performance of various electronic devices that use the EMC 110.

In an example, the amount of ion trapping agents in the composition that comprises the EMC 110 is in a range of approximately zero (0) wt. % and approximately three (3) wt. %. In another example, the amount of ion trapping agents in the composition is in a range of approximately zero point one (0.1) wt. % and approximately one (1) wt. %. Although specific ranges are given, other ranges may be used.

In an example, the EMC 110 is also comprised of a biodegradable stress modifier or an absorbing agent. The stress modifier is used in the EMC 110 to mitigate mechanical stresses that arise from three-dimensional changes, thereby preventing cracks and delamination in the epoxy and the electronic components that are encased in the EMC 110. The stress modifier also helps with thermal cycling performance, improves adhesion, prevents warping and deformation, and increases the overall reliability and longevity of electronic devices. In an example, the stress modifier of the EMC 110 is epoxidized soyabean oil or another biodegradable material.

In an example, the amount of stress modifier/absorbing agent in the composition that comprises the EMC 110 is in a range of approximately zero (0) wt. % and approximately three (3) wt. %. In another example, the amount of stress modifier/absorbing agent in the composition is in a range of approximately zero point one (0.1) wt. % and approximately one (1) wt. %. Although specific ranges are given, other ranges may be used.

In an example, the EMC 110 also includes a coupling agent. The coupling agent improves a compatibility between the bio-based epoxy resin and basalt powder, which leads to a more uniform and robust EMC 110. For example, the coupling agent prevents agglomeration and ensures a more homogeneous material. In an example, the coupling agent is a silane coupling agents such as, for example, Aminoethylaminopropyltrimethoxysilane.

In an example, the amount of coupling agent in the composition that comprises the EMC 110 is in a range of approximately zero (0) wt. % and approximately five (5) wt. %. In another example, the amount of coupling agent in the composition is in a range of approximately zero point one (0.1) wt. % and approximately three (3) wt. %. Although specific ranges are given, other ranges may be used.

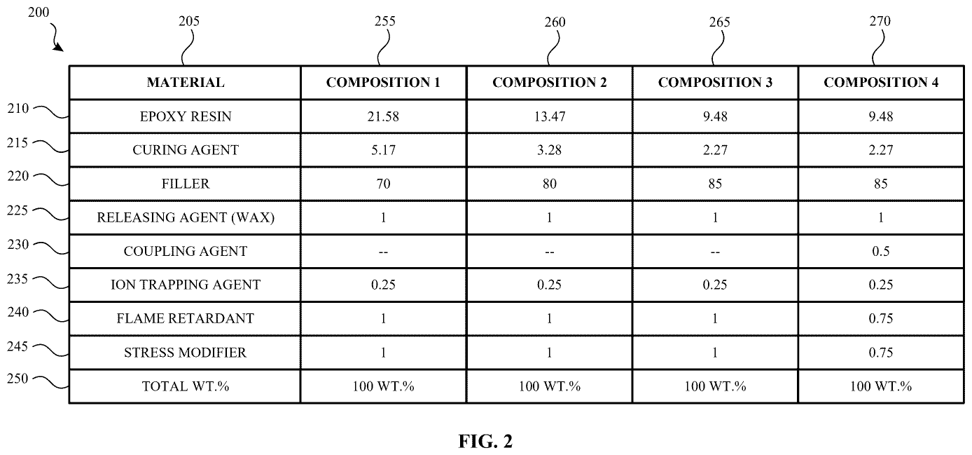

FIG. 2 is a table 200 that includes four example compositions for a bio-based EMC according to an example. In an example, each of the four example compositions may be used to create the EMC 110 shown and described with respect to FIG. 1. In an example, each of the compositions, Composition 1 255, Composition 2 260, Composition 3 265 and Composition 4 270, are created using the various materials 205 shown in the table 200 and discussed with respect to FIG. 1. Although specific compositions are shown and described, other compositions may be created and used for the EMC 110.

In an example and as shown in the table 200, Composition 1 255 includes 21.58 wt. % of an epoxy resin 210; 5.17 wt. % of a curing agent 215; 70 wt. % of a filler (e.g., basalt powder) 220; 1 wt. % of a releasing agent 225; no coupling agent 230; 0.25 wt. % of an ion trapping agent 235; 1 wt. % of a flame retardant 240 and 1 wt. % of a stress modifier 245 for a total wt. % 250 of 100.

In another example, Composition 2 260 includes 13.47 wt. % of an epoxy resin 210; 3.28 wt. % of a curing agent 215; 80 wt. % of a filler 220; 1 wt. % of a releasing agent 225; no coupling agent 230; 0.25 wt. % of an ion trapping agent 235; 1 wt. % of a flame retardant 240 and 1 wt. % of a stress modifier 245 for a total wt. % 250 of 100.

Another composition for an EMC is shown as Composition 3 265. In this example, Composition 3 265 includes 9.48 wt. % of an epoxy resin 210; 2.27 wt. % of a curing agent 215; 85 wt. % of a filler 220; 1 wt. % of a releasing agent 225; no coupling agent 230; 0.25 wt. % of an ion trapping agent 235; 1 wt. % of a flame retardant 240 and 1 wt. % of a stress modifier 245 for a total wt. % 250 of 100.

In yet another example, Composition 4 270 includes 9.48 wt. % of an epoxy resin 210; 2.27 wt. % of a curing agent 215; 85 wt. % of a filler 220; 1 wt. % of a releasing agent 225; 0.5 of a coupling agent 230; 0.25 wt. % of an ion trapping agent 235; 0.75 wt. % of a flame retardant 240 and 0.75 wt. % of a stress modifier 245 for a total wt. % 250 of 100.

As previously discussed, the compositions, along with the associated weight percentages of the various materials 205 are for example purposes only.

In addition to the various environmental benefits, the EMC described herein has similar, and in some cases, better physical, mechanical, and thermal properties when compared with conventional EMCs. Some of these properties, will be described in greater detail below.

A coefficient of thermal expansion (CTE) is a property that indicates the extent at which a material expands when heated. In an example, two CTE values (e.g., CTE1 and CTE2) were determined for the various compositions of the EMC described herein.

For example, CTE1 and CTE2 of the EMC were determined using a thermomechanical analyzer in which the test conditions were set as follows: a sample piece of EMC was heated from 25° C. to 280° C. at a rate of 10° C. per minute (° C./min) and the load was 0.1 Newton (N).

CTE1 was calculated in temperature range of 25° C.-100° C. and CTE2 was calculated in a temperature range of 140° C.-260° C. Using these test conditions, CTE1 is in a range of approximately 10 parts per million per degree Celsius (ppm/° C.) and approximately 40 ppm/° C. In another example, CTE1 is in a range of approximately 12 ppm/° C. and approximately 30 ppm/° C.

Additionally, CTE2 is in a range of approximately 20 ppm/° C. and approximately 110 ppm/° C. In another example, CTE2 is in a range of approximately 25 ppm/° C. and approximately 100 ppm/° C. Although specific ranges are given, these are for example purposes only.

Another property associated with the EMC described herein is thermal conductivity. Thermal conductivity is an essential characteristic of EMCs and relates to an ability of the EMC to effectively and efficiently dissipate heat generated by active components (e.g., processors, transistors, power elements) encapsulated by the EMC. Heat dissipation prevents overheating, which can lead to performance issues and/or premature component failure.

The thermal conductivity of the EMC described herein was tested using a sample having a thickness of eight millimeters (8 mm). In an example, the thermal conductivity of the EMC is in a range of approximately 0.1 watts per meter per Kelvin (W/m·K) and approximately 3 W/m·K. In another example, the thermal conductivity of the EMC is in a range of 0.2 W/m·K and approximately 2 W/m·K.

A viscosity of the EMC was also tested. Viscosity helps ensure proper mold filling, processing efficiency, void reduction, thermal performance, stress management, consistency, and equipment compatibility. Proper control and optimization of viscosity are crucial for achieving high-quality, reliable encapsulation of electronic components.

In an example, the viscosity of the EMC was measured using a parallel plate with a twenty-five (25) millimeter (mm) diameter and geometry of one (1) mm. Additionally, measurements were performed at a temperature in a range between 175° C. to 190° C. As a result, the viscosity of the EMC described herein is in a range of approximately 2 Pascal-seconds (Pa·s) and approximately 20 Pa·s. In another example, the viscosity of the EMC is in a range of approximately 4 Pa·s and approximately 10 Pa·s, although other ranges may be used.

The flexural modulus of the EMC described herein was also tested. High modulus materials have a higher resistance to deformation under stress compared to lower modulus materials. Thus, the higher the modulus, the more structurally stable the EMC will be. For example, during the assembly and manufacturing process, an encapsulated electronic device may be subjected to various mechanical forces. An EMC with an optimal flexural modulus ensures that electronic devices can withstand these forces without deforming or breaking.

The flexural modulus of the EMC described herein was tested using a three-point bend test that applies force at a midpoint of a rectangular portion of the EMC which was freely supported at either end. A thickness, width and length of rectangular portion of the EMC was as follows: four (4) mm, ×ten (10) mm×eighty (80) mm. Additionally, the test was performed at a crosshead speed of one (1) mm/min and test temperature was 25° C. Based on these test conditions, the flexural modulus of the EMC is in a range of approximately 5 gigapascals (GPa) to 35 GPa. In another example, the flexural modulus of the EMC is in a range of approximately 7 GPa and approximately 25 GPa, although other ranges may be used.

Specific gravity compares the density of a substance to the density of a reference substance. In this example, the specific gravity of the EMC of the present disclosure was measured in air and distilled water with a test temperature of 25° C. A weight of a sample piece of the EMC was maintained in the range of 2 grams (g) to 4 g. Based on these test conditions, the specific gravity of the EMC is in a range of approximately 1 gram per cubic centimeter (g/cm³) and approximately 3 g/cm³. In another example, the specific gravity of the EMC is in a range of approximately 1.7 g/cm³ and approximately 2.5 g/cm³.

A glass transition temperature (Tg) is a temperature at which an amorphous or semi-crystalline material, transitions from a hard state into a softer, more pliable or rubbery state and vice versa. Understanding this temperature is essential for determining the operating temperature range of the EMC.

Accordingly, the Tg of the EMC of the present disclosure was tested using a test temperature in the range 30 degrees Celsius (° C.) to 260° C., with a heating rate of 10° C. per minute. A weight of the EMC was in a range of 5 milligrams (MG)-20 mg. Additionally, two runs (e.g., heat-cool-heat) were carried out during testing. Based on this testing procedure, the EMC has a Tg value of in a range of approximately 80° C. and approximately 160° C. In another example, the EMC has a Tg value of approximately 130° C. and approximately 150° C.

Another property of the EMC described herein is gelation point. Gelation point helps to determine the optimum molding time and curing cycle of the EMC. The gelation point of the EMC was determined using the following test conditions. A test temperature was set at 190° C. and powder samples were placed on a plate of a rheometer. Under these conditions, the gelation point of the EMC described herein is in a range of approximately 42 seconds and approximately 180 seconds. In another example, the gelation time is in a range of 60 seconds to 120 seconds, although other ranges may be used.

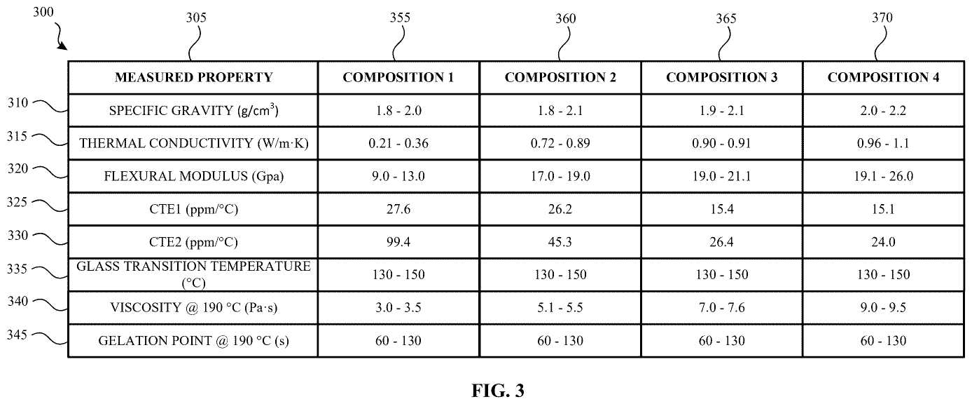

FIG. 3 is a table 300 that includes properties for four example compositions of a bio-based EMC according to an example. In an example, each of the four example compositions shown in table 300 are similar to the four example compositions shown and described with respect to FIG. 2. For example, Composition 1 255 in FIG. 2 that is comprised of the various materials shown and described with respect to FIG. 2 has the measured properties 305 of Composition 1 355 shown and described with respect to FIG. 3. Likewise, Composition 2 260 of FIG. 2 has the measured properties 305 of Composition 2 360. Although specific properties are shown and described, other properties may be manifest.

As shown in FIG. 3, Composition 1 355 has a specific gravity 310 in range of approximately 1.8 g/cm³ and approximately 2.0 g/cm³ and has a thermal conductivity 315 in a range of approximately 0.21 W/m·K and approximately 0.36 W/m·K. Composition 1 355 also has a flexural modulus 320 in a range of approximately 9.0 Gpa and approximately 13.0 Gpa, has a CTE1 325 of approximately 27.6 ppm/° C., a CTE2 330 of 99.4 ppm/° C. and a glass transition temperature 335 in range of approximately 130° C. and approximately 150° C. In an example, Composition 1 355 has a viscosity 340 at 190° C. in a range of approximately 3.0 Pa·s and approximately 3.5 Pa·s and a gelation point 345 at 190° C. in a range of approximately 60 seconds and approximately 130 seconds.

In another example, Composition 2 360 has a specific gravity 310 in range of approximately 1.8 g/cm³ and approximately 2.1 g/cm³ and has a thermal conductivity 315 in a range of approximately 0.72 W/m·K and approximately 0.89 W/m·K. Composition 2 360 also has a flexural modulus 320 in a range of approximately 17.0 Gpa and approximately 19.0 Gpa, has a CTE1 325 of approximately 26.2 ppm/° C., a CTE2 330 of 45.3 ppm/° C. and a glass transition temperature 335 in range of approximately 130° C. and approximately 150° C. In an example, Composition 2 360 has a viscosity 340 at 190° C. in a range of approximately 5.1 Pa·s and approximately 5.5 Pa·s and a gelation point 345 at 190° C. in a range of approximately 60 seconds and approximately 130 seconds.

As also shown in the table 300, Composition 3 365 has a specific gravity 310 in range of approximately 1.9 g/cm³ and approximately 2.1 g/cm³ and has a thermal conductivity 315 in a range of approximately 0.90 W/m·K and approximately 0.91 W/m·K. The Composition 3 365 also has a flexural modulus 320 in a range of approximately 19.0 Gpa and approximately 21.1 Gpa, has a CTE1 325 of approximately 15.4 ppm/° C., a CTE2 330 of 26.4 ppm/° C. and a glass transition temperature 335 in range of approximately 130° C. and approximately 150° C. In an example, the Composition 3 365 has a viscosity 340 at 190° C. in a range of approximately 7.0 Pa·s and approximately 7.6 Pa·s and a gelation point 345 at 190° C. in a range of approximately 60 seconds and approximately 130 seconds.

In this example, Composition 4 370 has a specific gravity 310 in range of approximately 2.0 g/cm³ and approximately 2.2 g/cm³ and has a thermal conductivity 315 in a range of approximately 0.96 W/m·K and approximately 1.1 W/m·K. Composition 4 370 also has a flexural modulus 320 in a range of approximately 19.1 Gpa and approximately 26.0 Gpa, has a CTE1 325 of approximately 15.1 ppm/° C., a CTE2 330 of 24.0 ppm/° C. and a glass transition temperature 335 in range of approximately 130° C. and approximately 150° C. In an example, Composition 4 370 has a viscosity 340 at 190° C. in a range of approximately 9.0 Pa·s and approximately 9.5 Pa·s and a gelation point 345 at 190° C. in a range of approximately 60 seconds and approximately 130 seconds.

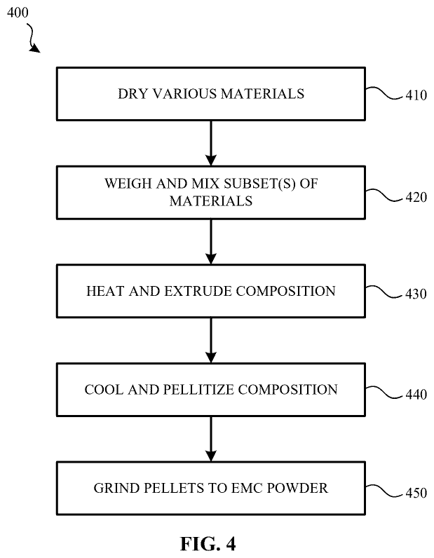

FIG. 4 illustrates a method 400 for creating a bio-based EMC powder that may be used to create a bio-based EMC according to an example. In an example, the materials used to create the EMC powder are the materials 205 in the table 200 shown and described with respect to FIG. 2.

In an example, the method 400 begins by drying (410) the various materials (e.g., additives and fillers) that will be used to create the EMC powder. The materials are dried for a duration of time and/or temperature that is based, at least in part, on thermal properties of the materials so as to avoid any moisture absorption. For example, any fillers, releasing agents, coupling agents, ion trapping agents, flame retardants and/or stress modifiers are dried using any suitable drying apparatus and/or technique. For example, basalt powder may be dried at 100° C. for three hours; biodegradable wax may be dried at 100° C. for one hour; the ion trapping agent may be dried at 100° C. for an hour; and the flame retardant may be dried at 100° C. for an hour. Although specific temperatures and times are discussed, these are for example purposes only.

In response to the materials being dried, individual components are weighed and subsequently mixed (420). In an example, the weight of the various materials is based, at least in part, on a desired weight percentage of the material(s) and/or based, at least in part, on desired properties of the EMC. Additionally, and for the mixing step, the materials are divided into a first subset of materials and a second subset of materials. For example, the first subset of materials includes the epoxy resin, the curing agent, the coupling agent and the stress modifier.

When the first subset of materials have been weighed, the first subset of materials are mixed together to form a first mixture. In an example, the first subset of materials are mixed in a high-speed centrifugal mixer in a range of approximately 300 revolutions per minute (RPM) and approximately 1000 RPM. In an example, the first subset of materials are mixed for a duration of time in a range of approximately 100 seconds and approximately 500 seconds. For example, the first subset of materials may be mixed at 300 RPM for 100 seconds, at 500 RPM for 300 seconds and/or at 1000 RPM for 500 seconds. Additionally, a vacuum pressure is set and approximately two (2) kilopascal (kPa). Although specific values are given, other values may be used when mixing the first subset of materials.

When the second subset of materials have been weighed, the second subset of materials are mixed together to form a second mixture. In an example, the second subset of materials includes the filler (e.g., basalt powder), the flame retardant, the releasing agent (e.g., wax) and the ion trapping agent. In an example, the second subset of materials are mixed using high-speed centrifugal mixer in a range of approximately 700 RPM and approximately 1500 RPM.

In an example, the second subset of materials are mixed for a duration of time in a range of approximately 300 seconds and approximately 500 seconds. For example, the second subset of materials may be mixed at 700 RPM for 300 seconds, at 1000 RPM for 500 seconds and/or at 1500 RPM for 500 seconds. Additionally, a vacuum pressure is set and approximately two (2) kPa. Although specific values are given, other values may be used when mixing the second subset of materials. In an example, during the mixing of the first subset of materials and the second subset of materials, degassing is also performed to remove trapped air and/or volatile gasses which can cause defects (e.g., voids or bubbles) in the final material.

In response to the first subset of materials being mixed and the second subset of materials being mixed, the first mixture and the second mixture are mixed together to form the EMC composition. In an example, the first mixture and the second mixture are simultaneously mixed in a range of approximately 100 RPM and approximately 1500 RPM at a time duration in a range of approximately 100 seconds and approximately 500 seconds. For example, the first mixture and the second mixture are mixed at 100 RPM for 100 seconds, at 300 RPM for 300 seconds, at 1000 RPM for 500 seconds and/or at 1500 RPM for 500 seconds. Additionally, a vacuum pressure is set and approximately two (2) kPa. Although specific values are given, other values may be used when mixing the first mixture and the second mixture. In an example, during the mixing of the various mixtures, degassing is also performed.

The method 400 also includes heating and extruding (430) the composition. For example, in response to the first mixture and the second mixture being mixed together to form the EMC composition, the EMC composition is provided to a three-dimensional (3D) composer where it is subjected to heat and pressure. The 3D composer, along with a high temperature and pressure helps ensure that the fillers are well integrated and that the composition will be extruded as filament.

When the composition has been extruded, the composition is cooled and palletized (440). For example, the composition is rapidly cooled and subsequently cut into small pellets (e.g., using a shredder). The pellets are then ground (450) into an EMC powder that is subsequently used to create the bio-based EMC of the present disclosure.

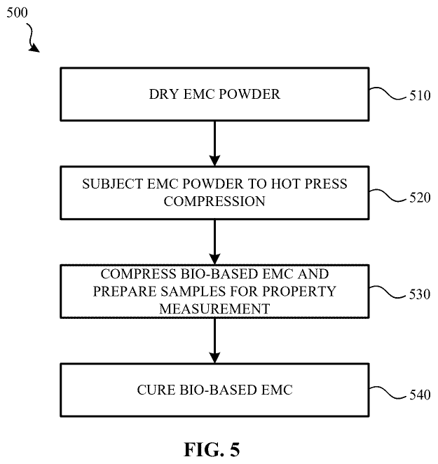

FIG. 5 illustrates a method 500 for creating a bio-based EMC according to an example. In an example, the method 500 may be used to create the EMC 110 shown and described with respect to FIG. 1. Additionally, the method 500 may use the EMC powder that was created using the various operations of the method 400 shown and described with respect to FIG. 4.

In an example, the method 500 begins by drying (510) the bio-based EMC powder. The EMC powder is dried for a duration of time and/or at a temperature that is based, at least in part, on the thermal properties of the bio-based EMC powder. For example, the EMC powder may be dried at a temperature between 80° C. and 100° C. for between one and two hours.

When the bio-based EMC powder has been dried, the EMC powder is compressed (520) (e.g., using hot press compression). In an example, the EMC powder is subjected to the hot press compression for a duration of time in a range between approximately three minutes and approximately fifteen minutes at a temperature of approximately 190° C.

The EMC powder is then compressed (530) into a bio-based EMC subsequently prepared for property measurements such as previously described. The bio-based EMC is then cured (540). In an example, the bio-based EMC is cured for a duration of time in a range between approximately two hours and approximately seven hours at a temperature of approximately 190° C.

Based on the above, examples of the present disclosure describe an epoxy molding compound (EMC) for an electronic device, comprising: a bio-based filler material having a first weight percentage in a range of sixty weight percentage and ninety weight percentage of a total material composition of the EMC; and a bio-based epoxy resin having a second weight percentage in a range of one weight percentage and a thirty weight percentage of the total material composition of the EMC. In an example, the bio-based filler material is basalt powder. In an example, the EMC also includes a bio-based stress modifier having a weight percentage of three or less of the total material composition of the EMC. In an example, the EMC also includes one or more of a curing agent, a releasing agent, a coupling agent, an ion trapping agent and a flame retardant. In an example, the EMC has a specific gravity in a range of 1 gram per cubic centimeter (g/cm³) and 3 g/cm³. In an example, the EMC has a thermal conductivity in a range of 0.1 watts per meter per Kelvin (W/m·K) and 3 W/m·K. In an example, the EMC has a flexural modulus in a range of 5 gigapascals (GPa) and 35 GPa. In an example, the EMC has a first coefficient of thermal expansion (CTE) in a range of 10 parts per million per degree Celsius (ppm/° C.) and 40 ppm/° C., and a second CTE in a range of 20 ppm/° C. and 110 ppm/° C. In an example, the EMC has a glass transition temperature in a range of 80 degrees Celsius (° C.) and 160° C. In an example, the EMC has a viscosity in a range of 2 Pascal-seconds (Pa·s) and 20 Pa·s, at a temperature of 190 degrees Celsius (° C.). In an example, the EMC has a gelation point in a range of 42 seconds and 180 seconds, at a temperature of 190 degrees Celsius (° C.).

Examples also describe an epoxy molding compound (EMC) for an electronic device, comprising: a bio-based filling means having a first weight percentage in a range of sixty weight percentage and ninety weight percentage of a total material composition of the EMC; and an epoxy resin means having a second weight percentage in range of one weight percentage and thirty weight percentage of the total material composition of the EMC. In an example, the bio-based filling means is basalt powder. In an example, the epoxy resin means is a bio-based epoxy resin. In an example, the EMC also includes a bio-based stress modification means having a weight percentage of three or less of the total material composition of the EMC. In an example, the EMC also includes one or more of a curing means, a releasing means, a coupling means, an ion trapping means and a flame retardant means. In an example, the EMC has a thermal conductivity in a range of 0.1 watts per meter per Kelvin (W/m·K) and 3 W/m·K. In an example, the EMC has a flexural modulus in a range of 5 gigapascals (GPa) and 35 GPa.

Examples also describe an electronic device, comprising: a substrate; a semiconductor die communicatively coupled to the substrate; and a bio-based epoxy molding compound (EMC) encapsulating the semiconductor die, the bio-based EMC being comprised of at least ninety percent by weight of bio-based materials. In an example, the bio-based EMC comprises a basalt powder.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An epoxy molding compound (EMC) for an electronic device, comprising:
a bio-based filler material having a first weight percentage in a range of sixty weight percentage and ninety weight percentage of a total material composition of the EMC; and
a bio-based epoxy resin having a second weight percentage in a range of one weight percentage and a thirty weight percentage of the total material composition of the EMC.

2. The EMC of claim 1, wherein the bio-based filler material is basalt powder.

3. The EMC of claim 1, further comprising a bio-based stress modifier having a weight percentage of three or less of the total material composition of the EMC.

4. The EMC of claim 1, further comprising one or more of a curing agent, a releasing agent, a coupling agent, an ion trapping agent and a flame retardant.

5. The EMC of claim 1, wherein the EMC has a specific gravity in a range of 1 gram per cubic centimeter (g/cm³) and 3 g/cm³.

6. The EMC of claim 1, wherein the EMC has a thermal conductivity in a range of 0.1 watts per meter per Kelvin (W/m·K) and 3 W/m·K.

7. The EMC of claim 1, wherein the EMC has a flexural modulus in a range of 5 gigapascals (GPa) and 35 GPa.

8. The EMC of claim 1, wherein the EMC has a first coefficient of thermal expansion (CTE) in a range of 10 parts per million per degree Celsius (ppm/° C.) and 40 ppm/° C., and a second CTE in a range of 20 ppm/° C. and 110 ppm/° C.

9. The EMC of claim 1, wherein the EMC has a glass transition temperature in a range of 80 degrees Celsius (° C.) and 160°C.

10. The EMC of claim 1, wherein the EMC has a viscosity in a range of 2 Pascal-seconds (Pa·s) and 20 Pa·s, at a temperature of 190 degrees Celsius (° C.).

11. The EMC of claim 1, wherein the EMC has a gelation point in a range of 42 seconds and 180 seconds, at a temperature of 190 degrees Celsius (° C.).

12. An epoxy molding compound (EMC) for an electronic device, comprising:
a bio-based filling means having a first weight percentage in a range of sixty weight percentage and ninety weight percentage of a total material composition of the EMC; and
an epoxy resin means having a second weight percentage in range of one weight percentage and thirty weight percentage of the total material composition of the EMC.

13. The EMC of claim 12, wherein the bio-based filling means is basalt powder.

14. The EMC of claim 12, wherein the epoxy resin means is a bio-based epoxy resin.

15. The EMC of claim 12, further comprising a bio-based stress modification means having a weight percentage of three or less of the total material composition of the EMC.

16. The EMC of claim 12, further comprising one or more of a curing means, a releasing means, a coupling means, an ion trapping means and a flame retardant means.

17. The EMC of claim 12, wherein the EMC has a thermal conductivity in a range of 0.1 watts per meter per Kelvin (W/m·K) and 3 W/m·K.

18. The EMC of claim 12, wherein the EMC has a flexural modulus in a range of 5 gigapascals (GPa) and 35 GPa.

19. An electronic device, comprising:
a substrate;
a semiconductor die communicatively coupled to the substrate; and
a bio-based epoxy molding compound (EMC) encapsulating the semiconductor die, the bio-based EMC being comprised of at least ninety percent by weight of bio-based materials.

20. The electronic device of claim 19, wherein the bio-based EMC comprises a basalt powder.
